(19) United States
(12) Patent Application Publication
(10) Pub. No.: US 2021/0309828 A1
(43) Pub. Date: Oct. 7, 2021

(54) SEMICONDUCTOR-ENCAPSULATING RESIN COMPOSITION, SEMICONDUCTOR DEVICE, AND METHOD FOR FABRICATING THE SEMICONDUCTOR DEVICE

(71) Applicant: Panasonic Intellectual Property Management Co., Ltd., Osaka (JP)

(72) Inventors: Hikaru SADA, Mie (JP); Chika ARAYAMA, Mie (JP)

(73) Assignee: Panasonic Intellectual Property Management Co., Ltd., Osaka (JP)

(21) Appl. No.: 17/263,074

(22) PCT Filed: Jul. 10, 2019
(86) PCT No.: PCT/JP2019/027393

§ 371 Date: Jan. 25, 2021

(30) Foreign Application Priority Data
Jul. 27, 2018 (JP) 2018-141597

(51) Int. Cl. C08K 3/36; C08K 3/08; C08K 5/00; C08K 3/04; H01L 23/29; H01L 21/56

(52) U.S. Cl. CPC C08K 3/36; C08K 3/08; C08K 5/0041; C08K 3/04; C08K 2003/0881; H01L 21/565; C08K 2201/005; C08K 2201/001; H01L 23/295

(57) ABSTRACT

A semiconductor-encapsulating resin composition includes a thermosetting resin, a filler, and a colorant. The filler has a mean particle size falling within the range from 0.5 μm to 15.0 μm. The colorant has an electrical resistivity of 1.0 Ω·m or more.

### TECHNICAL FIELD

The present invention generally relates to a semiconductor-encapsulating resin composition, a semiconductor device, and a method for fabricating the semiconductor device, and more particularly relates to a semiconductor-encapsulating resin composition for use to form an encapsulant covering a semiconductor element, a semiconductor device including an encapsulant formed out of the encapsulating resin composition, and a method for fabricating such a semiconductor device.

### BACKGROUND ART

When a semiconductor chip such as a transistor or an IC needs to be encapsulated, resin encapsulation is often carried out in the art to increase the productivity and cut down the costs. The resin encapsulation is carried out by molding a semiconductor-encapsulating resin composition, including an epoxy resin, a curing agent, a curing accelerator, an inorganic filler, and a colorant, for example, to form an encapsulant (see, for example, Patent Literature 1). According to Patent Literature 1, aniline black is used as a colorant to reduce electrification while the semiconductor-encapsulating resin composition is being molded and to increase the coloring ability of the encapsulant.

Meanwhile, NAND flash memories to be built in semiconductor packages such as eMMC and SSD have been increasingly required to have even larger storage capacity. To meet this demand, multiple semiconductor chips sometimes need to be arranged in a single semiconductor package or stacked one on top of another. Furthermore, to meet the increasing demand for electronic devices with even higher functionality and further decreased thickness, the encapsulant also needs to have its thickness decreased to keep the semiconductor package as thin as possible.

### CITATION LIST

### Patent Literature

Patent Literature 1: JP 2003-327792 A

### SUMMARY

It is therefore an object of the present invention to provide a semiconductor-encapsulating resin composition with the ability to reduce the light-transmitting property of an encapsulant for a semiconductor device while reducing the chances of causing an increase in the electrical conductivity of the encapsulant.

Another object of the present invention is to provide a semiconductor device including the semiconductor-encapsulating resin composition.

A semiconductor-encapsulating resin composition according to an aspect of the present invention contains: a thermosetting resin as Component (A); a filler as Component (B); and a colorant as Component (C). The filler as the Component (B) has a mean particle size falling within a range from 0.5 μm to 15.0 μm. The colorant as the Component (C) has an electrical resistivity of 1.0 Ω·m or more.

A semiconductor device according to another aspect of the present invention includes: a substrate; a semiconductor element mounted on the substrate; and an encapsulant covering the semiconductor element. The encapsulant is formed out of a cured product of the semiconductor-encapsulating resin composition described above.

A method for fabricating a semiconductor device according to still another aspect of the present invention is a method for fabricating a semiconductor device including: a substrate; a semiconductor element mounted on the substrate; and an encapsulant covering the semiconductor element. The method includes forming the encapsulant by compression-molding the semiconductor-encapsulating resin composition described above.

### BRIEF DESCRIPTION OF DRAWINGS

FIG. 1 is a cross-sectional view schematically illustrating a semiconductor device according to an embodiment of the present invention.

### DESCRIPTION OF EMBODIMENTS

An exemplary embodiment of the present invention will now be described. In the following description, the “solid content” of a semiconductor-encapsulating resin composition refers herein to the content of the rest of the semiconductor-encapsulating resin composition other than volatile components thereof such as a solvent. Note that the embodiment to be described below is only an exemplary one of various embodiments of the present invention and should not be construed as limiting. Rather, the exemplary embodiment may be readily modified in various manners depending on a design choice or any other factor without departing from the scope of the present invention.

First, it will be described exactly how the present inventors perfected our invention.

As the content of a colorant added to an encapsulant for a semiconductor device is increased to reduce the light-transmitting property of the encapsulant, the electrical conductivity of the encapsulant increases, thus increasing the chances of causing a short-circuit in the semiconductor device and possibly causing a failure in the semiconductor device. In addition, decreasing the thickness of the encapsulant for the semiconductor device allows incoming light to transmit through the encapsulant more easily. This makes the internal structure of the semiconductor device (such as the structure of its substrate and semiconductor elements) more transparent and seen through the encapsulant, thus increasing the chances of information about the internal structure of the semiconductor device leaking out, which is a problem.

Thus, the present inventors acquired the basic idea of our invention for overcoming such a problem by providing a semiconductor-encapsulating resin composition with the ability to reduce the light-transmitting property of an encapsulant for a semiconductor device and also reduce the chances of causing an increase in the electrical conductivity of the encapsulant.

A semiconductor-encapsulating resin composition according to this embodiment contains: a thermosetting resin as Component (A) (hereinafter simply referred to as a “thermosetting resin (A)”); a filler as Component (B) (hereinafter simply referred to as a “filler (B)”); and a colorant as Component (C) (hereinafter simply referred to as a “colorant (C)”). The filler (B) has a mean particle size falling within a range from 0.5 μm to 15.0 μm. The colorant (C) has an electrical resistivity of 1.0 Ω·m or more.

This embodiment allows an encapsulant for a semiconductor device to be formed by molding a semiconductor-encapsulating resin composition.

In the semiconductor-encapsulating resin composition according to this embodiment, setting the mean particle size of the filler (B) at a value falling within the range from 0.5 μm to 15.0 μm allows the filler (B) to scatter the incoming light and also allows the colorant (C) to absorb the incoming light, thus making the light-transmitting property of the encapsulant reducible. This ensures sufficient concealability even if the thickness of the encapsulant, which is formed by molding the semiconductor-encapsulating resin composition, is decreased. In addition, the colorant (C) has an electrical resistivity of 1.0 Ω·m or more, and therefore, will not cause an increase in the electrical conductivity of the encapsulant. This reduces the light-transmitting property of the encapsulant and also reduces the chances of causing an increase in the electrical conductivity of the encapsulant. Thus, the semiconductor-encapsulating resin composition according to this embodiment improves the concealability of the internal structure of a semiconductor device even if the thickness of the encapsulant for the semiconductor device is decreased.

In particular, according to this embodiment, when the semiconductor-encapsulating resin composition is cured and molded into a cured product with a thickness of 90 μm, the light ray transmittance at a wavelength of 550 nm of the cured product is suitably less than 1%. In that case, even if the semiconductor-encapsulating resin composition is molded into a cured product with a relatively small thickness, the light-transmitting property of the encapsulant is still reducible and the electrical conductivity of the encapsulant does not increase easily. Note that the semiconductor-encapsulating resin composition's having a light ray transmittance less than 1% at a wavelength of 550 nm when cured and formed into a cured product with a thickness of 90 μ,m defines the property of the semiconductor-encapsulating resin composition, not limiting the thickness of the encapsulant formed out of the semiconductor-encapsulating resin composition. That is to say, the thickness of the encapsulant may be equal to, greater than, or less than, 90 μ,m, whichever is appropriate.

Furthermore, the encapsulating resin composition according to this embodiment improves, even if the encapsulant is formed to have a decreased thickness, the concealability of the internal structure of the semiconductor device as described above, thus reducing the chances of the incoming light impinging on semiconductor elements and other members on the substrate. In general, when an encapsulant is subjected to laser marking, for example, the laser beam is transmitted through the encapsulant, thus enhancing the risk of doing significant damage to the semiconductor elements and other members. In contrast, the semiconductor-encapsulating resin composition according to this embodiment reduces the chances of the laser beam doing significant damage to the semiconductor elements and other members even when the encapsulant is subjected to laser marking.

Furthermore, generally speaking, as the content of a colorant added to the encapsulant is increased to reduce the light-transmitting property of the encapsulant and thereby ensure concealability, the electrical conductivity of the encapsulant increases, thus causing a short-circuit more frequently in the semiconductor device. In contrast, the semiconductor-encapsulating resin composition according to this embodiment hardly causes an increase in the electrical conductivity of the encapsulant as described above, thus causing insulation failures in the semiconductor device much less often.

As can be seen from the foregoing description, the semiconductor-encapsulating resin composition according to this embodiment allows the substrate and semiconductor elements to be encapsulated appropriately, reduces the light-transmitting property of the encapsulant for the semiconductor device, and reduces the chances of causing an increase in the electrical conductivity of the encapsulant during the manufacturing process of the semiconductor device. This improves the concealability of the internal structure of the semiconductor elements and other members even if the encapsulant is formed out of the semiconductor-encapsulating resin composition to have a decreased thickness. In addition, this also reduces, even if the thickness of the encapsulant is decreased, the chances of the semiconductor elements being damaged by a laser beam at the time of laser marking, and also lowers the frequency of occurrence of insulation failures in the semiconductor device.

The respective components of the semiconductor-encapsulating resin composition will now be described in detail.

The thermosetting resin (A) contains an epoxy resin. The epoxy resin may contain at least one component selected from the group consisting of glycidyl ether type epoxy resins, glycidyl amine type epoxy resins, glycidyl ester type epoxy resins, and olefin oxide type (alicyclic) epoxy resins. More specifically, the epoxy resin suitably contains one or more components selected from the group consisting of: alkyl phenol novolac-type epoxy resins such as a phenol novolac-type epoxy resin and a cresol novolac-type epoxy resin; naphthol novolac-type epoxy resins; phenol aralkyl-type epoxy resins having a phenylene skeleton or a biphenylene skeleton, for example; biphenyl aralkyl-type epoxy resins; naphthol aralkyl-type epoxy resins having a phenylene skeleton or a biphenylene skeleton, for example; multifunctional epoxy resins such as a triphenolmethane type epoxy resin and an alkyl-modified triphenolmethane type epoxy resin; triphenylmethane type epoxy resins; tetrakisphenol ethane type epoxy resins; dicyclopentadiene type epoxy resin; stilbene type epoxy resins; bisphenol type epoxy resins such as a bisphenol A type epoxy resin and a bisphenol F type epoxy resin; biphenyl type epoxy resins; naphthalene type epoxy resins; alicyclic epoxy resins; bromine containing epoxy resins such as a bisphenol A type bromine containing epoxy resin; glycidyl amine-type epoxy resins obtained by reaction between a polyamine such as diaminodiphenylmethane and isocyanuric acid and epichlorohydrin; and glycidyl ester-type epoxy resins obtained by reaction between a polybasic acid such as phthalic acid or dimer acid and epichlorohydrin. Among other things, the epoxy resin particularly suitably contains one or more components selected from the group consisting of bisphenol A type epoxy resins, phenol novolac type epoxy resins, cresol novolac type epoxy resins, biphenyl type epoxy resins, and triphenylphosphine type epoxy resins.

The thermosetting resin (A) suitably contains a curing agent. The curing agent is used to cure the epoxy resin. The curing agent may contain one or more components selected from the group consisting of phenolic compounds, acid anhydrides, and functional compounds that generate phenolic hydroxyl groups, for example.

If the curing agent contains a phenolic compound, the curing agent may include any of monomers, oligomers, and polymers each having two or more phenolic hydroxyl groups in one molecule. For example, the curing agent may contain one or more components selected from the group consisting of phenol novolac resins, cresol novolac resins, biphenyl type novolac resins, triphenylmethane type resins, naphthol novolac resins, phenol aralkyl resins, and biphenyl aralkyl resins.

If the curing agent contains a phenolic compound, the hydroxyl group equivalent of the phenolic compound per epoxy group equivalent of the epoxy resin is suitably at least 0.5, more suitably 0.9 or more. The hydroxyl group equivalent is suitably 1.5 or less, more suitably 1.2 or less.

If the curing agent contains an acid anhydride, the curing agent may contain one or more components selected from the group consisting of phthalic anhydride, trimellitic anhydride, pyromellitic anhydride, maleic anhydride, benzophenonetetracarboxylic anhydride, hexahydrophthalic anhydride, tetrahydrophthalic anhydride, methylhexahydrophthalic anhydride, methyltetrahydrophthalic anhydride, and polyazeleic anhydride.

If the curing agent contains a functional compound producing a phenolic hydroxyl group, the curing agent may contain a compound producing a phenolic hydroxyl group by being heated. More specifically, the curing agent may contain benzoxazines that open the ring when heated to generate a phenolic hydroxyl group.

The thermosetting resin (A) may contain a curing accelerator. The curing accelerator may accelerate the reaction (curing reaction) between an epoxy group of the epoxy resin and a hydroxyl group of the curing agent. Examples of the curing accelerator include organic phosphines such as triphenylphosphine, tributylphosphine, and tetraphenylphosphonium tetraphenylborate; tertiary amines such as 1,8-diaza-bicyclo (5,4,0) undecene-7 (DBU), triethylenediamine, and benzyldimethylamine; and imidazoles such as 2-methylimidazole, 2-ethyl-4-methylimidazole, 2-phenylimida7ole, and 2-phenyl-4-methylimidazole. The curing accelerator may contain at least one component selected from this group.

The content of the curing accelerator may be adjusted appropriately according to the content of the curing agent such as an epoxy resin and a phenolic resin included in the thermosetting resin (A).

The mean particle size of the filler (B) falls within the range from 0.5 μm to 15.0 μm as described above. Setting the mean particle size of the filler (B) at a value falling within this range allows the filler (B) to scatter incoming light that irradiates the cured product of the semiconductor-encapsulating resin composition inside the cured product. This makes the light-transmitting property of the encapsulant reducible in the semiconductor device. This improves the concealability of the internal structure such as semiconductor elements even if the thickness of the encapsulant is decreased in the semiconductor device. Furthermore, improving the concealability of the internal structure of the semiconductor device reduces the chances of the semiconductor elements and other members being damaged by a laser beam while the encapsulant is subjected to laser marking.

Setting the mean particle size of the filler (B) at 0.5 μm or more may curb an increase in the viscosity of the semiconductor-encapsulating resin composition. This makes the effect of wire sweeping reducible when an encapsulant is formed out of the semiconductor-encapsulating resin composition. In addition, setting the mean particle size of the filler (B) at 15.0 μm or less reduces the chances of light penetrating the gap between particles of the filler (B) in the cured product made of the semiconductor-encapsulating resin composition. The mean particle size of the filler (B) more suitably falls within the range from 3.0 μm to 14.0 μm and even more suitably falls within the range from 4.0 μm to 12.0 μm. Note that the mean particle size is a volume-based median diameter calculated based on measured values of a particle size distribution by laser diffraction and scattering method and may be obtained by using a commercially available laser diffraction and scattering type particle size distribution analyzer.

As long as the mean particle size of the filler (B) falls within the range from 0.5 μm to 15.0 μm, the filler (B) may also contain particles with a particle size less than 0.5 μm and particles with a particle size greater than 15.0 μm.

In the filler (B), particles having a particle size of 10.0 μm or less suitably account for 40% to 90% of the total content of the filler (B). This allows the filler (B) to more easily scatter the light that irradiates the cured product. This makes the light-transmitting property of the encapsulant reducible in the semiconductor device. Therefore, this improves the concealability of the internal structure such as semiconductor element even if the thickness of the encapsulant is decreased in the semiconductor device. Furthermore, improving the concealability of the internal structure of the semiconductor device reduces the chances of the semiconductor elements and other members being damaged by a laser beam while the encapsulant is subjected to laser marking. In the filler (B), particles having a particle size of 10.0 μm or less more suitably account for 50% to 90%, even more suitably account for 70% to 90%, of the total content of the filler (B).

The filler (B) may contain at least one component selected from the group consisting of, for example, fused silica such as fused spherical silica, crystalline silica, alumina, and silicon nitride. Among other things, the filler (B) suitably contains fused silica. The filler (B) may contain at least one component selected from the group consisting of alumina, crystalline silica, and silicon nitride.

The content of the filler (B) in the semiconductor-encapsulating resin composition suitably falls within the range from 60% by mass to 90% by mass with respect to the solid content of the semiconductor-encapsulating resin composition.

The colorant (C) is a component that may absorb incoming light in the semiconductor-encapsulating resin composition. This may reduce the light-transmitting property of the encapsulant formed out of the semiconductor-encapsulating resin composition. This improves the concealability of the internal structure such as semiconductor elements even if the thickness of the encapsulant is decreased in the semiconductor device. Furthermore, this also reduces the chances of the semiconductor elements and other members being damaged by a laser beam while the encapsulant of the semiconductor device is subjected to laser marking.

In addition, the colorant (C) also contributes to reducing an increase in the electrical conductivity of the encapsulant for the semiconductor device, thus ensuring electrical insulation properties for the encapsulant. This reduces, even if the thickness of the encapsulant for the semiconductor device is decreased, the chances of causing insulation failures in the semiconductor device.

The colorant (C) suitably contains at least one component selected from the group consisting of titanium black, black iron oxide, phthalocyanine pigments, and perylene black. Each of these components has an electrical resistivity of 1.0 Ω·m or more. This makes the light-transmitting property of the encapsulant formed out of the semiconductor-encapsulating resin composition further reducible. The phthalocyanine-based pigment is suitably a phthalocyanine-based black pigment. If the colorant (C) contains a pigment selected from this group, the content of the pigment with respect to the total solid content of the semiconductor-encapsulating resin composition suitably falls within the range from 0.4% by mass to 2.0% by mass. This may further reduce the light-transmitting property of the encapsulant formed out of the semiconductor-encapsulating resin composition.

Particularly, when the colorant (C) contains titanium black, the content of the titanium black with respect to the total solid content of the semiconductor-encapsulating resin composition suitably falls within the range from 0.4% by mass to 2.0% by mass. This may further reduce the light-transmitting property of the encapsulant formed out of the semiconductor-encapsulating resin composition and further reduce an increase in the electrical conductivity of the encapsulant.

When the colorant (C) contains titanium black, the content of the titanium black with respect to the total content of the colorant (C) suitably falls within the range from 10% by mass to 80% by mass.

The colorant (C) suitably contains a dye. Even so, the light-transmitting property of the encapsulant formed out of the semiconductor-encapsulating resin composition is further reducible. Examples of the dye include aniline black and azine-based dyes. If the colorant (C) contains a dye, the content of the dye with respect to the total solid content of the semiconductor-encapsulating resin composition suitably falls within the range from 0.1% by mass to 0.4% by mass. This may further reduce the light-transmitting property of the encapsulant formed out of the semiconductor-encapsulating resin composition.

The semiconductor-encapsulating resin composition may contain additional coloring components other than the colorant (C). The semiconductor-encapsulating resin composition suitably further contains carbon black as Component (D) (hereinafter simply referred to as “carbon black (D)”). In that case, the content of the carbon black (D) with respect to the total solid content of the semiconductor-encapsulating resin composition suitably falls within the range from 0.1% by mass to 0.6% by mass. Setting the content of the carbon black (D) at 0.1% by mass makes the light-transmitting property of the encapsulant formed out of the semiconductor-encapsulating resin composition reducible particularly significantly. Setting the content of the carbon black (D) at 0.6% by mass or less may further reduce an increase in the electrical conductivity of the encapsulant, thus keeping the electrical insulation properties of the encapsulant good enough.

If the semiconductor-encapsulating resin composition contains both the colorant (C) and carbon black (D), then the combined content of the colorant (C) and the carbon black (D) with respect to the total solid content of the semiconductor-encapsulating resin composition suitably falls within the range from 0.5% by mass to 2.5% by mass. Setting the combined content at 0.5% by mass or more may further reduce the light-transmitting property of the encapsulant formed out of the semiconductor-encapsulating resin composition. Setting the combined content at 2.5% by mass or less may further reduce an increase in the electrical conductivity of the encapsulant, thus keeping the electrical insulation properties of the encapsulant good enough.

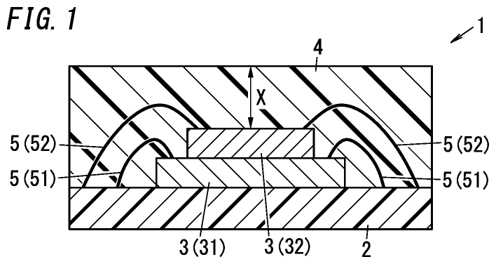

The semiconductor-encapsulating resin composition may contain some additives other than the components described above unless the advantages of this embodiment are impaired significantly. Examples of such additives include release agents, flame retardants, low stress agents, and ion trapping agents. The coupling agent may contribute to increasing the affinity between the thermosetting resin (A) and the filler (B) and increasing the adhesiveness of the encapsulant 4 (see FIG. 1) to the substrate 2. The coupling agent may contain, for example, at least one component selected from the group consisting of a silane coupling agent, a titanate coupling agent, an aluminum coupling agent, and an aluminum/zirconium coupling agent. Examples of the silane coupling agent include glycidoxysilanes such as γ-glycidoxypropyltrimethoxysilane, γ-glycidoxypropylmethyldiethoxysilane, and β-(3,4-epoxy cyclohexyl) ethyltrimethoxysilane; amino silanes such as N-β (aminoethyl)-γ-aminopropyl trimethoxysilane, γ-aminopropyltriethoxysilane, and N-phenyl-γ-aminopropyltrimethoxysilane; alkyl silanes; ureido silanes; and vinyl silanes.

The release agent may contain, for example, at least one component selected from the group consisting of carnauba wax, stearic acid, montanic acid, carboxyl group-containing polyolefin, ester wax, polyethylene oxide, and metal soap. The flame retardant may contain, for example, at least one component selected from the group consisting of magnesium hydroxide, aluminum hydroxide, and red phosphorus.

The low-stress agent may contain, for example, at least one component selected from the group consisting of a silicone elastomer, a silicone resin, a silicone oil, and butadiene-based rubber. The butadiene-based rubber may contain, for example, at least one component selected from the group consisting of a methyl acrylate-butadiene-styrene copolymer and a methyl methacrylate-butadiene-styrene copolymer.

The ion trapping agent may contain, for example, at least one of a hydrotalcite compound or a hydrated oxide of a metallic element. The hydrated oxide of the metallic element may contain, for example, at least one component selected from the group consisting of a hydrated oxide of aluminum, a hydrated oxide of bismuth, a hydrated oxide of titanium, and a hydrated oxide of zirconium.

Next, an exemplary method for producing the semiconductor-encapsulating resin composition will be described. The semiconductor-encapsulating resin composition may be produced by kneading the above-described respective materials of the semiconductor-encapsulating resin composition while heating those materials. More specifically, materials including the epoxy resin, the curing agent, the curing accelerator, the filler, and the colorant are mixed together with a mixer, a blender, or any other machine, kneaded together while being heated with a kneading machine such as a heat roller or a kneader, and then cooled to room temperature, thereby obtaining a semiconductor-encapsulating resin composition. Optionally, the semiconductor-encapsulating resin composition may be pulverized into powder. The powder may be either tableted or granulated. Alternatively, the encapsulating resin composition may also be applied and then dried to turn into a sheet shape. While these materials are kneaded together, the heating temperature may fall within the range from 80° C. to 130° C., for example. However, this temperature is only an example and should not be construed as limiting.

The semiconductor-encapsulating resin composition suitably has a viscosity equal to or less than 10.0 Pa·s. This lowers the frequency of occurrence of wire sweeping while a semiconductor device is being fabricated by encapsulating the semiconductor element with a semiconductor-encapsulating resin composition. The viscosity more suitably falls within the range from 1.0 Pa·s to 6.0 Pa·s. Note that the viscosity of the semiconductor-encapsulating resin composition corresponds to the “slit viscosity” to be described later for specific examples, and the method and condition for measuring the viscosity are also as will be described later for the specific examples.

The cured product of the semiconductor-encapsulating resin composition may be obtained, for example, in the following manner. Specifically, the cured product may be obtained by heating, and thereby curing, the semiconductor-encapsulating resin composition at a temperature of 150-180° C. for 90 to 300 seconds. The curing conditions, such as the heating temperature and heating duration, may be set appropriately according to the chemical makeup of the semiconductor-encapsulating resin composition or the type of the semiconductor device to fabricate. When measured under the condition including a temperature of 25° C. and an applied voltage of 500 V, the volume resistivity of the cured product of the semiconductor-encapsulating resin composition is suitably 1×10¹⁴ Ω·m or more. When measured under the condition including a temperature of 150° C. and an applied voltage of 500 V, the volume resistivity of the cured product of the semiconductor-encapsulating resin composition is suitably 1×10¹⁰ Ω·m or more. This allows, when an encapsulant to cover a semiconductor element is formed out of the semiconductor-encapsulating resin composition, the insulation properties of the encapsulant to be kept sufficiently low. The cured product of the semiconductor-encapsulating resin composition may be obtained by, for example, putting the semiconductor-encapsulating resin composition into a mold of a compression molding machine and applying pressure to the compression molding machine by the compression molding method to be described later.

Next, an exemplary semiconductor device 1 including an encapsulant 4 formed out of the semiconductor-encapsulating resin composition and a method for fabricating such a semiconductor device 1 will be described with reference to FIG. 1.

The semiconductor device 1 according to this embodiment includes a substrate 2, semiconductor elements 3 mounted on the substrate 2, and an encapsulant 4 covering the semiconductor elements 3. The encapsulant 4 is a package that defines the profile of the semiconductor device 1 and is formed out of a cured product of the semiconductor-encapsulating resin composition. Specifically, the semiconductor device 1 shown in FIG. 1 is a single-side-encapsulated semiconductor device. The semiconductor device 1 includes: a semiconductor element 3 (hereinafter referred to as a “first semiconductor element 31”) mounted on the substrate 2; another semiconductor element 3 (hereinafter referred to as a “second semiconductor element 32”) stacked on the first semiconductor element 31; wires 5 (hereinafter referred to as “first wires 51”) electrically connecting the first semiconductor element 31 to the substrate 2; wires 5 (hereinafter referred to as “second wires 52”) electrically connecting the second semiconductor element 32 to the substrate 2; and the encapsulant 4 covering the semiconductor elements 3. In the semiconductor device 1 shown in FIG. 1, two semiconductor elements 3 are stacked one on top of the other. However, the number of the semiconductor elements 3 may be determined appropriately according to the intended use, shape, and dimensions of the semiconductor device.

The semiconductor elements 3 such as the first semiconductor element 31 and the second semiconductor element 32 may be implemented as an integrated circuit, a largescale integrated circuit (LSI), a transistor, a thyristor, a diode, or a solid-state image sensor. The semiconductor elements 3 may also be novel power devices such as SiC and GaN devices or electronic parts such as an inductor or a capacitor. The substrate 2 may be a lead frame, a wiring board, or an interposer, for example.

Known wires may be used as the first wires 51 and the second wires 52. Any wires may be used as long as the wires may electrically connect the substrate 2 and the semiconductor elements 3 together.

Specific examples of the semiconductor device 1 include: insertion type packages such as a Mini, a D pack, a D2 pack, a To22O, a To3P and a dual inline package (DIP); and surface mount packages such as a quad flat package (QFP), a small outline package (SOP), a small outline J-lead package (SOJ), a ball grid array (BGA), and a system in package (SiP).

The encapsulant 4 of the semiconductor device 1 suitably has a thickness X (as indicated by the double-headed arrow in FIG. 1) of 20 μm to 90 μm. Setting the thickness X of the encapsulant 4 at 90 μm or less facilitates decreasing the thickness of the semiconductor device.

The ratio of the mean particle size of the filler (B) in the encapsulant to the thickness X of the encapsulant 4 is suitably one-seventh or less. This may reduce the light-transmitting property of the encapsulant 4 in the semiconductor device 1. This allows, even if the thickness of the encapsulant 4 is decreased, the internal structure to be concealed easily. This reduces the chances of the semiconductor elements being damaged by a laser beam while the encapsulant 4 is subjected to laser marking.

The encapsulant 4 may be formed out of the cured product of the semiconductor-encapsulating resin composition by molding the semiconductor-encapsulating resin composition by pressure molding. Examples of the pressure molding include injection molding, transfer molding, and compression molding.

The encapsulant 4 of the semiconductor device 1 is suitably formed by compression molding. That is to say, a method for fabricating the semiconductor device 1 suitably includes forming the encapsulant 4 by compression-molding the semiconductor-encapsulating resin composition. Specifically, in fabricating the semiconductor device 1, the substrate 2, the semiconductor element 3 mounted on the substrate 2, and the wires 5 for electrically connecting the substrate 2 and the semiconductor element 3 together are arranged and the semiconductor-encapsulating resin composition is injected into a compression molding machine after having been melted. Next, the semiconductor-encapsulating resin composition is cured by compressing the mold of the compression molding machine in the machine while heating the mold. This allows the encapsulant 4 to be formed such that the encapsulant 4 covers the semiconductor element 3. In this manner, a semiconductor device 1, including the substrate 2, the semiconductor element 3 mounted on the substrate 2, and the encapsulant 4 covering the semiconductor element 3, may be obtained.

When the semiconductor-encapsulating resin composition is molded by compression molding, the compression pressure is suitably equal to or higher than 5.0 MPa. The compression pressure is more suitably 7.0 MPa or more, even more suitably 10.0 MPa or more. The heating temperature (mold temperature) suitably falls within the range from 150° C. to 180° C. The heating temperature is more suitably equal to or higher than 160° C., even more suitably equal to or higher than 170° C. The heating duration suitably falls within the range from 90 seconds to 300 seconds.

Alternatively, the semiconductor-encapsulating resin composition may also be molded by transfer molding. If the semiconductor-encapsulating resin composition is molded by transfer molding, the pressure to be applied when the semiconductor-encapsulating resin composition is injected into the die, for example, may be set at 8.0 MPa or more. The heating duration may be equal to or longer than 90 seconds, for example.

In the transfer molding process, after the encapsulant 4 has been formed in the mold, the semiconductor device 1 is suitably unloaded with the mold opened and then subjected to post curing by heating the encapsulant 4 with a thermostat. The heating condition for post curing may include a heating temperature falling within the range from 160° C. to 200° C. and a heating duration falling within the range from 4 hours to 10 hours, for example.

### EXAMPLES

Next, the present invention will be described more specifically by way of illustrative examples. Note that the examples to be described below are only examples of the present invention and should not be construed as limiting the scope of the present invention.

1. Preparation of Semiconductor-Encapsulating Resin Composition

In respective examples and comparative examples, the components shown in the following Tables 1 and 2 were compounded together, mixed for 30 minutes in a blender such that the mixture would have uniform composition, kneaded, melted, and extruded while being heated at a temperature of 90° C., and then pulverized after having been cooled. In this manner, a granular semiconductor-encapsulating resin composition was obtained.

The details of the components shown in those tables are as follows:
Thermosetting resin: o-cresol novolac type epoxy resin, manufactured by DIC Corporation, product name N663EXP;
Curing agent: phenolic resin, manufactured by Meiwa Plastic Industries, Ltd., product name H-3M;
Curing accelerator: TPP (triphenylphosphine), manufactured by Hokko Chemical Industry Co., Ltd.;
Fused silica A: manufactured by Denka Co. Ltd., product name FB510FC, mean primary particle size 11.8 μm;
Fused silica B: manufactured by Denka Co. Ltd., product name FB4DPM, mean primary particle size 4.6 μm;
Fused silica C: manufactured by Denka Co. Ltd., product name FB8752FC, mean primary particle size 17.1 μm;
Colorant A: titanium black (manufactured by Ako Kasei Co., Ltd., product name Tilack DTM-B), electrical resistivity 1.0 Ω·m;
Colorant B: oil-soluble azine dye (manufactured by Orient Chemical Industries Co., Ltd., product number Oripack B-30), electrical resistivity 1.0 Ω·m; and
Carbon black: manufactured by Mitsubishi Chemical Corporation, product number # 40, electrical resistivity 1×10⁻² Ω·m.

2. Evaluation

The semiconductor-encapsulating resin composition prepared as described in section 1 was evaluated in terms of the following items (1) and (2). In addition, a cured product of the semiconductor-encapsulating resin composition prepared as described in section 1 and a semiconductor device including an encapsulant formed out of the cured product were evaluated in terms of the following items (3)-(5).

(1) Viscosity (Slit Viscosity)

The semiconductor-encapsulating resin composition was put into a pot of a TM1vI type transfer molding machine (manufactured by Tatara Seisakusho) and injected into the mold of the transfer molding machine at a mold temperature of 175° C. and an intra-pot pressure of 9.8 MPa. In this case, the pressure when the semiconductor-encapsulating resin composition flowed through a portion with a thickness of 0.4 mm inside the mold was measured to calculate the viscosity (slit viscosity). The results are shown in the following Tables 1 and 2.

(2) Cl Ion Content and Na Ion Content

10 g (converted into a solid content) of the semiconductor-encapsulating resin composition was extracted in a methanol aqueous solution including 50 g of methanol and 10 g of water, and the extracted liquid thus obtained was measured with an ion chromatograph (column: C-C3) to calculate the content of sodium ion (Na+) in the extracted liquid. In the same way, the extracted liquid was measured with an ion chromatograph (column: C-SA2) to calculate the content of chloride ion (Cl—) in the extracted liquid. The results are shown in the following Tables 1 and 2.

(3) Transmittance

The semiconductor-encapsulating resin composition was cured under the condition including a compression pressure of 9.8 MPa, a mold temperature of 175° C., and a heating duration of 180 seconds to obtain a cured product. Next, the cured product was cut off and polished to make a test piece with a thickness of 90 μm, a width of 10 mm, and a length of 20 mm. This test piece was irradiated with visible light (with a wavelength of 550 nm) by a spectrophotometer (manufactured by Shimadzu Corporation, MPC-3100) to measure its transmittance. The results are also shown in Tables 1 and 2.

(4) Volume Resistivity

The semiconductor-encapsulating resin composition was cured inside a mold with a diameter of 100 mm and a thickness of 3 mm under the condition including an injection pressure of 9.8 MPa, a mold temperature of 175° C., and a heating duration of 180 seconds to make a test piece. A DC voltage of 500 V was applied at an ordinary temperature (of 25° C.) to this test piece by an electrometer device (digital vibrating capacitor electrometer: TAKEDA RIKEN TR8411) to measure the volume resistivity of the test piece. In addition, the voltage was applied in the same way at a temperature of 150° C. to the test piece to measure the volume resistivity of the test piece. The results are also shown in Tables 1 and 2.

(5) Chip Transparency (Concealability)

The substrate, the semiconductor element mounted on the substrate, and the semiconductor-encapsulating resin composition were loaded into the mold of a compression molding machine (manufactured by TOWA JAPAN, FFT1030G) and molded under the condition including a mold temperature of 175° C., an injection pressure of 8 MPa, and a molding duration of 180 seconds, thereby fabricating a semiconductor device, of which the encapsulant had a thickness of 90 μm. In this semiconductor device, the degree of transparency of the semiconductor element was checked with the eye and the semiconductor device was rated under the following criteria. The results are shown in the following Tables 1 and 2:
Grade A: the semiconductor element could not be seen through the encapsulant;
Grade B: the color of the semiconductor element was recognizable through the encapsulant;
Grade C: the color and location of the semiconductor element were recognizable through the encapsulant; and
Grade D: the color and location of the semiconductor element were clearly recognizable through the encapsulant and some parts of the semiconductor element were not filled with the encapsulant.

TABLE 1

| | | | Examples | | | | | | | |
|---|---|---|---|---|---|---|---|---|---|---|
| | | | 1 | 2 | 3 | 4 | 5 | 6 | 7 | 8 |
| Composition | Thermosetting | o-cresol type epoxy | 12.7 | 12.7 | 12.7 | 12.7 | 12.7 | 12.7 | 12.7 | 12.7 |
| (% by mass) | resin | resin | | | | | | | | |
| | Curing agent | Phenolic resin | 6.8 | 6.8 | 6.8 | 6.8 | 6.8 | 6.8 | 6.8 | 6.8 |
| | Curing | TPP | 0.3 | 0.3 | 0.3 | 0.3 | 0.3 | 0.3 | 0.3 | 0.3 |
| | accelerator | | | | | | | | | |
| | Filler | Fused silica A | 80 | 80 | 80 | — | 80 | 80 | 80 | 80 |
| | | Fused silica B | — | — | — | 80 | — | — | — | — |
| | | Fused silica C | — | — | — | — | — | — | — | — |
| | | Mean particle size | 11.8 | 11.8 | 11.8 | 4.6 | 11.8 | 11.8 | 11.8 | 11.8 |
| | | [μm] | | | | | | | | |
| | | % of filler particles | 44.2 | 44.2 | 44.2 | 82.1 | 44.2 | 44.2 | 44.2 | 44.2 |
| | | with particle size of | | | | | | | | |
| | | 10 μm or less | | | | | | | | |
| | Colorant | Colorant A | 0.4 | 0.8 | 2.0 | 0.8 | 2.0 | 2.3 | 0.4 | — |
| | | Colorant B | — | — | — | — | — | — | — | 0.4 |
| | — | Carbon black | 0.1 | 0.4 | 0.5 | 0.4 | 0.6 | 0.5 | 0.4 | 0.4 |

| | | | | | | | | | |
|---|---|---|---|---|---|---|---|---|---|
| | Combined content (% by mass) of | 0.5 | 1.2 | 2.5 | 1.2 | 2.6 | 2.8 | 0.8 | 0.8 |
| | colorant and carbon black | | | | | | | | |
| Evaluation | Slit viscosity [Pa · s] | 3.8 | 4.2 | 4.9 | 4.5 | 5.0 | 7.6 | 4.0 | 4.4 |
| | Cl ion content [ppm] | 3 | 3 | 3 | 4 | 3 | 4 | 3 | 9 |
| | Na ion content [ppm] | 5 | 5 | 6 | 5 | 5 | 6 | 5 | 7 |
| | Light ray transmittance | 0.92 | 0.24 | 0.13 | 0.19 | 0.12 | 0.11 | 0.68 | 0.73 |
| | [%] at 550 nm | | | | | | | | |
| | Volume resistivity | 3.00E+14 | 3.20E+14 | 1.1E+14 | 2.6E+14 | 8.8E+13 | 8.6E+13 | 2.8E+14 | 2.9E+14 |
| | (at ordinary temperature) | | | | | | | | |
| | [Ω · m] | | | | | | | | |
| | Volume resistivity | 7.30E+10 | 4.3E+10 | 3.5E+10 | 3.1E+10 | 1.1E+10 | 1.2E+10 | 7.0E+10 | 4.1E+10 |
| | (at 150° C.) [Ω · m] | | | | | | | | |
| | Chip transparency | A | A | A | A | A | A | A | A |

TABLE 2

| | | | Examples | | | Comparative Examples | | | | |
|---|---|---|---|---|---|---|---|---|---|---|
| | | | 9 | 10 | 11 | 1 | 2 | 3 | 4 | 5 |
| Composition | Thermosetting | o-cresol type epoxy | 12.7 | 12.7 | 12.7 | 12.7 | 12.7 | 12.7 | 12.7 | 12.7 |
| (% by mass) | resin | resin | | | | | | | | |
| | Curing agent | Phenolic resin | 6.8 | 6.8 | 6.8 | 6.8 | 6.8 | 6.8 | 6.8 | 6.8 |
| | Curing | TPP | 0.3 | 0.3 | 0.3 | 0.3 | 0.3 | 0.3 | 03 | 0.3 |
| | accelerator | | | | | | | | | |
| | Filler | Fused silica A | 80 | 80 | — | 80 | — | — | — | — |
| | | Fused silica B | — | — | 80 | — | — | — | 80 | 80 |
| | | Fused silica C | — | — | — | — | 80 | 80 | — | — |
| | | Mean particle size | 11.8 | 11.8 | 4.6 | 11.8 | 17.1 | 17.1 | 4.6 | 4.6 |
| | | [μm] | | | | | | | | |
| | | % of filler particles | 44.2 | 44.2 | 82.1 | 44.2 | 38.7 | 38.7 | 82.1 | 82.1 |
| | | with particle size of | | | | | | | | |
| | | 10 μm or less | | | | | | | | |
| | Colorant | Colorant A | 0.4 | 0.2 | 0.4 | — | — | 0.4 | — | — |
| | | Colorant B | 0.1 | — | 1.0 | — | — | — | — | — |
| | — | Carbon black | 0.1 | 0.2 | — | 0.2 | 0.2 | 0.4 | 0.4 | 0.8 |

| | | | | | | | | | |
|---|---|---|---|---|---|---|---|---|---|
| Evaluation | Combined content (% by mass) of | 0.6 | 0.4 | 1.0 | 0.2 | 0.2 | 0.8 | 0.4 | 0.8 |
| | colorant and carbon black | | | | | | | | |
| | Slit viscosity [Pa · s] | 4.0 | 3.8 | 4.1 | 3.6 | 3.4 | 3.9 | 4.5 | 5.8 |
| | Cl ion content [ppm] | 6 | 3 | 26 | 2 | 3 | 3 | 3 | 4 |
| | Na ion content [ppm] | 7 | 5 | 18 | 6 | 5 | 5 | 5 | 6 |
| | Light ray transmittance | 0.81 | 1.12 | 1.02 | 4.14 | 5.22 | 3.25 | 1.08 | 0.2 |
| | [%] at 550 nm | | | | | | | | |
| | Volume resistivity | 3.00E+14 | 3.4E+14 | 2.5E+14 | 3.6E+14 | 3.2E+14 | 2.2E+14 | 8.2E+13 | 6.90E+13 |
| | (at ordinary temperature) [Ω · m] | | | | | | | | |
| | Volume resistivity | 5.1E+10 | 6.2E+10 | 6.1E+10 | 8.7E+10 | 8.1E+10 | 6.7E+10 | 1.2E+10 | 5.00E+09 |
| | (at 150° C.) [Ω · m] | | | | | | | | |
| | Chip transparency | A | B | B | C | D | D | B | A |

### REFERENCE SIGNS LIST

1 Semiconductor Device

2 Substrate

3 Semiconductor Element

4 Encapsulant

1. A semiconductor-encapsulating resin composition containing:
a thermosetting resin as Component (A);
a filler as Component (B); and
a colorant as Component (C),
the filler as the Component (B) having a mean particle size falling within a range from 0.5 μm to 15.0 μm,
the colorant as the Component (C) having an electrical resistivity of 1.0 Ω·m or more.

2. The semiconductor-encapsulating resin composition of claim 1, wherein
when the resin composition is cured and molded into a cured product having a thickness of 90 μm, a light ray transmittance at a wavelength of 550 nm or less of the cured product is less than 1%.

3. The semiconductor-encapsulating resin composition of claim 1, wherein
particles having a particle size of 10.0 μm or less in the filler as the Component (B) account for 40% to 90% of a total content of the filler as the Component (B).

4. The semiconductor-encapsulating resin composition of claim 1, wherein
the colorant as the Component (C) includes at least one pigment selected from the group consisting of titanium black, black iron oxide, a phthalocyanine-based pigment, and perylene black.

5. The semiconductor-encapsulating resin composition of claim 4, wherein
content of the pigment with respect to a total solid content of the semiconductor-encapsulating resin composition falls within a range from 0.4% by mass to 2.0% by mass.

6. The semiconductor-encapsulating resin composition of claim 1, wherein
the colorant as the Component (C) includes titanium black, and
content of the titanium black with respect to a total solid content of the semiconductor-encapsulating resin composition falls within a range from 0.4% by mass to 2.0% by mass.

7. The semiconductor-encapsulating resin composition of claim 1, wherein
the colorant as the Component (C) includes a dye, and
content of the dye with respect to a total solid content of the semiconductor-encapsulating resin composition falls within a range from 0.1% by mass to 0.4% by mass.

8. The semiconductor-encapsulating resin composition of any one of claim 1, wherein
the semiconductor-encapsulating resin composition has a viscosity falling within a range from 1.0 Pa·s to 10.0 Pa·s when the viscosity is measured under a condition including a temperature of 175° C. and a pressure of 9.8 MPa.

9. The semiconductor-encapsulating resin composition of claim 1, wherein
a cured product of the semiconductor-encapsulating resin composition has a volume resistivity of 1×10¹⁴ Ω·m or more when the volume resistivity is measured under a condition including a temperature of 25° C. and an applied voltage of 500 V, and
has a volume resistivity of 1×10¹⁰ Ω·m or more when the volume resistivity is measured under a condition including a temperature of 150° C. and an applied voltage of 500 V.

10. A semiconductor device comprising: a substrate; a semiconductor element mounted on the substrate; and an encapsulant covering the semiconductor element,
the encapsulant being formed out of a cured product of the semiconductor-encapsulating resin composition of claim 1.

11. The semiconductor device of claim 10, wherein
the encapsulant has a thickness of 90 μm or less.

12. The semiconductor device of claim 10, wherein
a ratio of a means particle size of the filler as the Component (B) to the thickness of the encapsulant is one-seventh or less.

13. A method for fabricating a semiconductor device including: a substrate; a semiconductor element mounted on the substrate; and an encapsulant covering the semiconductor element, the method comprising:
forming the encapsulant by compression-molding the semiconductor-encapsulating resin composition of claim 1.
